(19) United States
(12) Patent Application Publication
(10) Pub. No.: US 2025/0330730 A1
(43) Pub. Date: Oct. 23, 2025

(54) PIXEL AND IMAGE SENSOR INCLUDING THE SAME

(71) Applicant: Samsung Electronics Co., Ltd., Suwon-si (KR)

(72) Inventor: Haewon LEE, Suwon-si (KR)

(73) Assignee: Samsung Electronics Co., Ltd., Suwon-si (KR)

(21) Appl. No.: 19/027,060

(22) Filed: Jan. 17, 2025

(30) Foreign Application Priority Data
Apr. 17, 2024 (KR) 10-2024-0051171

(51) Int. Cl. H04N 25/77

(52) U.S. Cl. CPC H04N 25/77

(57) ABSTRACT

A pixel including a first photodiode and a second photodiode having a different light-receiving area from that of the first photodiode includes a semiconductor substrate, a first pixel region in the semiconductor substrate and having the first photodiode arranged therein, a second pixel region in the semiconductor substrate and having the second photodiode arranged therein, and a pixel isolation film at a surface where the first pixel region and the second pixel region are in contact with each other, wherein an area of the first pixel region is larger than an area of the second pixel region, and the pixel isolation film includes a first pixel isolation film and a second pixel isolation film, the second pixel isolation film separated from the first pixel isolation film.

### CROSS-REFERENCE TO RELATED APPLICATION

This application is based on and claims priority under 35 U.S.C. § 119 to Korean Patent Application No. 10-2024-0051171, filed on Apr. 17, 2024, in the Korean Intellectual Property Office, the disclosure of which is incorporated by reference herein in its entirety.

### BACKGROUND

The inventive concepts relate to pixels and image sensors including the same. More particularly, the inventive concepts relate to a layout structure of a pixel including a split photodiode structure.

Image sensors capture a two-dimensional (2D) or three-dimensional (3D) image of an object. Image sensors generate an image of an object by using a photoelectric conversion element, which reacts to the intensity of light reflected from the object. With the recent development of complementary metal-oxide semiconductor (CMOS) technology, CMOS image sensors using CMOS have been widely used. To increase the dynamic range of image sensors, split photodiode technology by which a pixel includes a plurality of photodiodes having different light-receiving areas is being developed. Research into obtaining image signals from a plurality of photodiodes of a split photodiode without degradation in image quality is required.

### SUMMARY

Some example embodiments of the inventive concepts provide a layout structure of a pixel capable of improving floating diffusion (FD) leakage (e.g., reducing, minimizing, or preventing FD leakage).

According to some example embodiments of the inventive concepts, a pixel may include a first photodiode and a second photodiode having a different light-receiving area from that of the first photodiode. The pixel may include a semiconductor substrate, a first pixel region in the semiconductor substrate and having the first photodiode therein, a second pixel region in the semiconductor substrate and having the second photodiode therein, and a pixel isolation film at a surface where the first pixel region and the second pixel region are in contact with each other, wherein an area of the first pixel region may be larger than an area of the second pixel region, and the pixel isolation film may include a first pixel isolation film and a second pixel isolation film, the second pixel isolation film separated from the first pixel isolation film.

According to some example embodiments of the inventive concepts, an image sensor may include a plurality of photodiodes having different light-receiving areas. The image sensor may include a semiconductor substrate of a first conductivity type, the semiconductor substrate including a first pixel region and a second pixel region, a first photodiode of a second conductivity type, the first photodiode in the first pixel region, a second photodiode of the second conductivity type, the second photodiode in the second pixel region, the second photodiode having a different light-receiving area than a light-receiving area of the first photodiode, a first floating diffusion region, the first floating diffusion region configured to accumulate charges of the first photodiode, and a third floating diffusion region, the third floating diffusion region configured to accumulate charges of the second photodiode, wherein the first floating diffusion region is in the first pixel region, and wherein the third floating diffusion region extends between the first pixel region and the second pixel region.

According to some example embodiments of the inventive concepts, an image sensor may include a plurality of pixels in a semiconductor substrate. Each pixel of the plurality of pixels may include a first photodiode, a second photodiode adjacent to the first photodiode and having a smaller light-receiving area than a light-receiving area of the first photodiode, a first transfer transistor having an end connected to the first photodiode and an opposite end connected to a first floating diffusion node, a first conversion gain transistor having an end connected to the first floating diffusion node and an opposite end connected to a second floating diffusion node, a second transfer transistor having an end connected to the second photodiode and an opposite end connected to a third floating diffusion node, a second conversion gain transistor having an end connected to the third floating diffusion node and an opposite end connected to a fourth floating diffusion node, a first switching transistor having an end connected to the second floating diffusion node and an opposite end connected to the third floating diffusion node, and a capacitor having an end connected to the fourth floating diffusion node and an opposite end connected to a pixel voltage source, wherein the first photodiode, the first transfer transistor, the first conversion gain transistor, the second conversion gain transistor, and the first switching transistor are in a first pixel region of the semiconductor substrate, the second photodiode and the second transfer transistor are in a second pixel region of the semiconductor substrate, the second transfer transistor, the first switching transistor, and the second conversion gain transistor share a region corresponding to the third floating diffusion node, and the region corresponding to the third floating diffusion node extends between the first pixel region and the second pixel region of the semiconductor substrate.

### BRIEF DESCRIPTION OF THE DRAWINGS

Example embodiments will be more clearly understood from the following detailed description taken in conjunction with the accompanying drawings in which:

FIG. 1 is a block diagram of an image sensor according to some example embodiments;

FIG. 2 is a circuit diagram of a pixel according to some example embodiments;

FIG. 3 is a timing diagram illustrating the operation of a pixel, according to some example embodiments;

FIG. 4A is a layout diagram of a pixel according to some example embodiments;

FIGS. 4B and 4C are cross-sectional views respectively taken along line A-A′ and line B-B′ in FIG. 4A according to some example embodiments;

FIG. 5 is a potential diagram of a pixel according to a comparative embodiment;

FIG. 6 is a potential diagram of a pixel according to some example embodiments of the inventive concepts;

FIG. 7A is a diagram illustrating the flow of charges in a pixel according to a comparative embodiment and FIGS. 7B and 7C are diagrams illustrating the flow of charges in a pixel according to some example embodiments of the inventive concepts;

FIGS. 8A and 8B are circuit diagrams of pixels according to some example embodiments;

FIGS. 9A, 9B, and 9C are circuit diagrams of pixels according to some example embodiments;

FIGS. 10A and 10B are diagrams illustrating the arrangements of pixels according to some example embodiments;

FIG. 11 is a block diagram of an electronic device including multiple camera modules according to some example embodiments; and

FIG. 12 is a detailed block diagram of a camera module in FIG. 11 according to some example embodiments.

### DETAILED DESCRIPTION

Hereinafter, some example embodiments are described with reference to the accompanying drawings.

In order to clearly explain the present inventive concepts in the drawings, parts that are not related to the description are omitted, and similar parts are given similar reference numerals throughout the specification. In the flowchart described with reference to the drawings, the order of operations may be changed, several operations may be merged, certain operations may be divided, and certain operations may not be performed.

Additionally, expressions written in the singular may be interpreted as singular or plural, unless explicit expressions such as “one” or “single” are used. Terms containing ordinal numbers, such as first, second, etc., may be used to describe various elements, but the elements are not limited by these terms. These terms may be used for the purpose of distinguishing one component from another.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

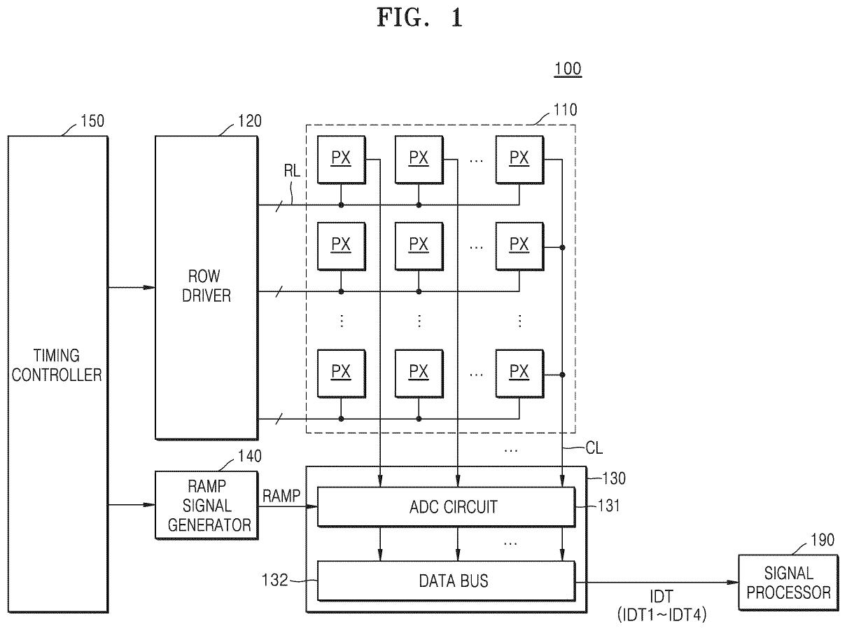

FIG. 1 is a block diagram of an image sensor 100 according to some example embodiments.

The image sensor 100 may be mounted on an electronic device, which has a function of sensing an image or light. For example, the image sensor 100 may be mounted on an electronic device, such as a camera, a smartphone, a wearable device, an Internet of things (IoT) device, an appliance, a table personal computer (PC), a personal digital assistant (PDA), a portable multimedia player (PMP), a navigation device, a drone, or an advanced driver assistance system (ADAS). The image sensor 100 may also be mounted on electronic devices that are used as components of vehicles, furniture, manufacturing facilities, doors, or various kinds of measuring equipment.

Referring to FIG. 1, the image sensor 100 may include a pixel array 110, a row driver 120, a readout circuit 130, a ramp signal generator 140, a timing controller 150, and a signal processor 190. The readout circuit 130 may include an analog-to-digital converter (ADC) circuit 131 and a data bus 132.

The pixel array 110 may include a plurality of pixels PX in a matrix. The pixels PX may be connected to a plurality of row lines RL and column lines CL. For example, each of the row lines RL may extend in a row direction and may be connected to pixels PX in one row. However, unlike FIG. 1, pixels PX in one row may be connected to different row lines RL. Each of the pixels PX may receive a control signal from the row driver 120 through a row line RL connected to each pixel PX.

According to some example embodiments, each of the pixels PX may include at least one photoelectric conversion element. The photoelectric conversion element may sense light and convert the light into one or more photocharges (e.g., one or more electrical charges, one or more electrical signals, etc.). For example, the photoelectric conversion element may include a device, such as an inorganic photodiode, an organic photodiode, a Perovskite photodiode, a photo transistor, a photogate, or a pinned photodiode, which includes an organic or inorganic material.

In some example embodiments, each of the pixels PX may include a plurality of photoelectric conversion elements (hereinafter, referred to as photodiodes). Photocharges generated by a photodiode in response to light during a certain exposure time may be referred to as a photocharge packet.

A microlens for light collection may be provided above each of the pixels PX or above a pixel group including adjacent pixels PX. Each of the pixels PX may sense light in a particular spectrum from light received through the microlens. For example, the pixel array 110 may include a red pixel converting light in a red spectrum into an electrical signal, a green pixel converting light in a green spectrum into an electrical signal, and a blue pixel converting light in a blue spectrum into an electrical signal. A color filter, which transmits light (e.g., selectively transmits light) in a particular spectrum (e.g., a particular wavelength spectrum), may be disposed above each of the pixels PX. However, example embodiments are not limited thereto. The pixel array 110 may include pixels, which convert light (e.g., incident light) in spectrums (e.g., wavelength spectra) other than the red, green, and blue spectrums into electrical signals.

According to some example embodiments, the pixels PX may have a multi-layer structure. Each of the pixels PX having a multi-layer structure may include stacked photodiodes each converting light in a different spectrum into an electrical signal so that electrical signals respectively corresponding to different colors may be generated from the photodiodes. In other words, electrical signals respectively corresponding to different colors may be output from a single pixel PX.

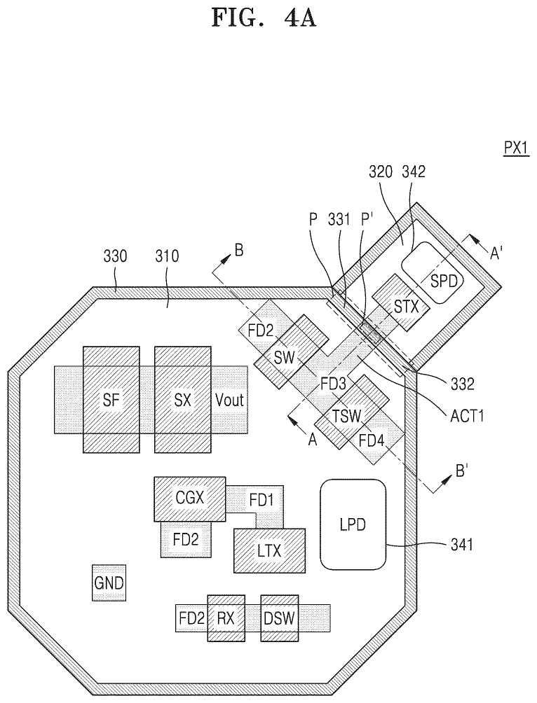

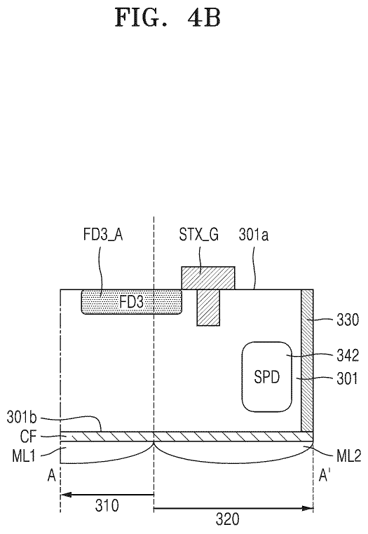

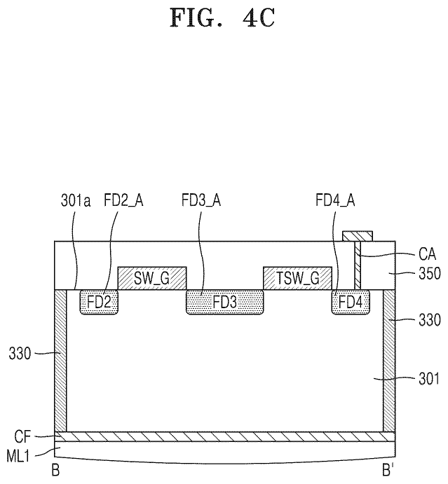

In some example embodiments, each of the pixels PX may have a split photodiode structure including at least two photodiodes configured to be exposed to light (incident light), wherein the two photodiodes may be exposed or reset independently of each other. For example, each pixel PX may include a large photodiode (LPD or referred to as a first photodiode), which has a large light-receiving area, and a small photodiode (SPD or referred to as a second photodiode), which has a small light-receiving area. In the pixel array 110, the pixel PX may operate in a dual conversion gain mode. According to the layout structure of the pixel PX of the inventive concepts, the number of contact regions causing floating diffusion (FD) leakage may be reduced by cutting a portion of a pixel isolation film between a large photodiode and a small photodiode and connecting the large photodiode to the small photodiode by using a floating diffusion region as a junction (e.g., through the cut portion of the pixel isolation film), and thus, noise may be improved (e.g., noise in electrical signals generated and/or transmitted by the pixel PX may be reduced, minimized, or prevented). This is described in detail with reference to FIG. 4A and other succeeding drawings below.

Each of the column lines CL may extend in a column direction and may be connected to pixels PX in one column. However, unlike FIG. 1, pixels PX in one column may be connected to different column lines CL. Each of the column lines CL may transmit reset signals and pixel signals of pixels PX in each row of the pixel array 110 to the readout circuit 130.

The timing controller 150 may control the timings of the row driver 120, the readout circuit 130, and the ramp signal generator 140. The timing controller 150 may provide a timing signal, which indicates an operation timing, to each of the row driver 120, the readout circuit 130, and the ramp signal generator 140.

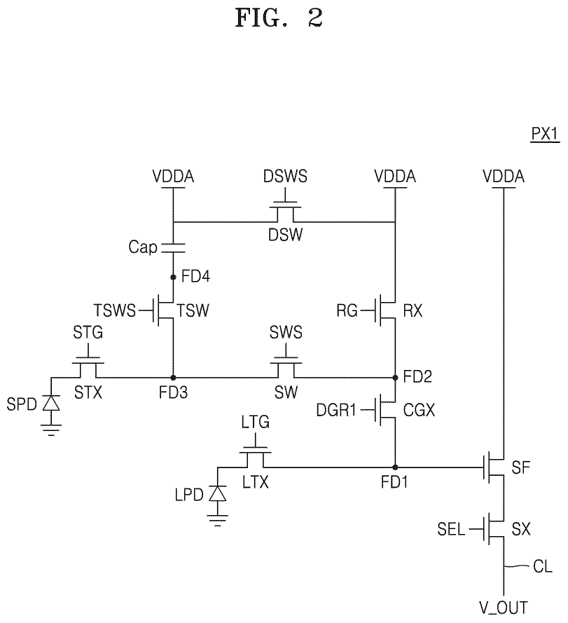

Under control by the timing controller 150, the row driver 120 may generate control signals for driving the pixel array 110 and provide the control signals to each of the pixels PX of the pixel array 110 through the row lines RL. Turning on and off transistors described below may be performed by a control signal provided by the row driver 120. For example, a first transfer transistor (LTX in FIG. 2) may be turned on in response to a first transfer control signal (LTG) at an active level (e.g., logic high) and may be turned off in response to the first transfer control signal (LTG) at an inactive level (e.g., logic low). The operations of the pixels PX according to the control signals provided by the row driver 120 are described below with reference to FIG. 2.

The row driver 120 may control the pixels PX of the pixel array 110 to sense incident light simultaneously or row-by-row. The row driver 120 may select pixels PX of each row and may control the selected pixels PX (e.g., pixels PX in one row) to output (or generate) reset signals and pixel signals through the column lines CL.

The readout circuit 130 may read out reset signals and pixel signals from pixels PX selected by the row driver 120 among the plurality of pixels PX. The readout circuit 130 may generate and output pixel values (or image signals), which correspond to a plurality of pixels PX, in row units by converting reset signals and pixel signals, which are received from the pixel array 110 through the column lines CL, into digital data by using a ramp signal RAMP from the ramp signal generator 140.

The ADC circuit 131 may include a plurality of ADCs respectively corresponding to the column lines CL. Each of the ADCs may compare a reset signal and a pixel signal, which are received through one of the column lines CL that corresponds to each ADC, with the ramp signal RAMP and may generate a pixel value based on a result of the comparison. For example, an ADC may remove a reset signal from a pixel signal and may generate a pixel value, i.e., an image signal, which indicates the amount of light sensed by a pixel PX. For example, as described below with reference to FIG. 2, an ADC may generate an image signal (e.g., a first image signal) in an LPD-H mode based on an LPD-H reset signal and an LPD-H pixel signal and may generate an image signal (e.g., a second image signal) in an LPD-L mode based on an LPD-L reset signal and an LPD-L pixel signal. An ADC may generate an image signal (e.g., a third image signal) in an SPD-H mode based on an SPD-H reset signal and an SPD-H pixel signal and may generate an image signal (e.g., a fourth image signal) in an SPD-L mode based on an SPD-L reset signal and an SPD-L pixel signal.

A plurality of image signals generated by the ADC circuit 131 may be output as image data IDT through the data bus 132. For example, the image data IDT may be provided to an image signal processor inside or outside the image sensor 100.

The data bus 132 may temporarily store and output a pixel value (or an image signal) from the ADC circuit 131. The data bus 132 may include a plurality of column memories and a column decoder. A plurality of pixel values stored in the column memories may be output as the image data IDT under control by the column decoder. For example, the data bus 132 may output a first image signal as first image data IDT1, a second image signal as second image data IDT2, a third image signal as third image data IDT3, and a fourth image signal as fourth image data IDT4.

The signal processor 190 may perform noise reduction, gain tuning, waveform shaping, interpolation, white balance, a gamma process, edge enhancement, binning, or the like on the image data IDT. According to some example embodiments, when the pixel array 110 operates in the LPD-H mode, the LPD-L mode, the SPD-H mode, and the SPD-L mode, which are described below with reference to FIG. 2, during a single frame period, the signal processor 190 may receive, from the data bus 132, the first image data IDT1 in the LPD-H mode, the second image data IDT2 in the LPD-L mode, the third image data IDT3 in the SPD-H mode, and the fourth image data IDT4 in the SPD-L mode and may generate an image having a high dynamic range (HDR) by merging the first to fourth image data IDT1, IDT2, IDT3, and IDT4. In some example embodiments, the signal processor 190 may be provided in a processor outside the image sensor 100.

FIG. 2 is a circuit diagram of a pixel according to some example embodiments. According to some example embodiments, a pixel PX1 of FIG. 2 may be included in the pixel array 110 in FIG. 1.

The pixel PX1 of FIG. 2 may include a capacitor Cap and a plurality of photodiodes and transistors, e.g., a first photodiode LPD, a second photodiode SPD, a first transfer transistor LTX, a second transfer transistor STX, a reset transistor RX, a drive transistor SF, a select transistor SX, a first conversion gain transistor CGX, a second conversion gain transistor TSW, a first switching transistor SW, and a second switching transistor DSW. In some example embodiments, the number (quantity) and configuration of transistors included in the pixel PX1 may vary.

The first photodiode LPD may have a large light-receiving area. The second photodiode SPD may have a smaller light-receiving area than the light-receiving area of the first photodiode LPD. The larger the light-receiving area of a photodiode, the more the photodiode may be exposed to incident light. Accordingly, the first photodiode LPD having a large light-receiving area may be used in a dark environment.

The first photodiode LPD and the second photodiode SPD may convert light incident from the outside (incident light) into an electrical signal. Photodiodes may generate charges according to light intensity (e.g., incident light intensity). The amount of charges generated by the first photodiode LPD and the second photodiode SPD may vary with an image capturing environment (e.g., low-or high-luminance). For example, the amount of charges generated by the first photodiode LPD may reach the full well capacity (FWC) of the first photodiode LPD in a high-luminance environment but not in a low-luminance environment.

Photocharge(s) generated by the first photodiode LPD in response to incident light is referred to as a first photocharge packet and photocharge(s) generated by the second photodiode SPD in response to incident light is referred to as a second photocharge packet.

The first transfer transistor LTX may transfer charges accumulated in the first photodiode LPD to a first floating diffusion node FD1. The second transfer transistor STX may transfer charges accumulated in the second photodiode SPD to a third floating diffusion node FD3. Charges generated by the second photodiode SPD may be accumulated (or stored) in the capacitor Cap when (e.g., based on) the second transfer transistor STX is turned on.

The first and second transfer transistors LTX and STX may be respectively controlled by first and second transfer control signals LTG and STG. The first floating diffusion node FD1 may receive charges from the first photodiode LPD and cumulatively stores the charges. The drive transistor SF may be controlled according to the amount of photocharges accumulated in the first floating diffusion node FD1.

As described above, the pixel PX1 may operate in a dual conversion gain mode. The dual conversion gain mode may include a low conversion gain mode and a high conversion gain mode. Conversion gain may refer to a ratio at which a photocharge packet accumulated in a floating diffusion node is converted into a voltage, and the unit of conversion gain may be uV/e. According to some example embodiments, a photocharge packet generated by each of the first photodiode LPD and the second photodiode SPD may be eventually transferred to and accumulated in the first floating diffusion node FD1, and an output voltage V_OUT may be output (transmitted) based on a voltage corresponding to the photocharge packet accumulated in the first floating diffusion node FD1. Here, conversion gain may vary with the capacitance of the first floating diffusion node FD1, and the output voltage V_OUT corresponding to the same photocharge packet may vary with a change in the conversion gain. As the capacitance of the first floating diffusion node FD1 increases, the conversion gain may decrease. As the capacitance of the first floating diffusion node FD1 decreases, the conversion gain may increase.

According to the operation of the plurality of transistors, the first floating diffusion node FD1 may be connected to a second floating diffusion node FD2, the third floating diffusion node FD3, and/or a fourth floating diffusion node FD4. The capacitance of a capacitor of the first floating diffusion node FD1 may vary according to whether the first floating diffusion node FD1 is connected to the second floating diffusion node FD2, the third floating diffusion node FD3, and/or the fourth floating diffusion node FD4. For example, when (based on) the first floating diffusion node FD1 is connected to the second floating diffusion node FD2 because the first conversion gain transistor CGX is turned on, the first floating diffusion node FD1 may be connected to a capacitor of the second floating diffusion node FD2 so that the capacitance of the capacitor of the first floating diffusion node FD1 may increase. In this case, it may be said that the pixel PX1 operates in the low conversion gain mode.

The first photodiode LPD may operate in the high conversion gain (HCG) mode (i.e., the LPD-H mode) in the lowest luminance section (e.g., a first luminance section) and may operate in the low conversion gain (LCG) mode (i.e., the LPD-L mode) in a luminance section (e.g., a second luminance section), which has a higher luminance than the first luminance section. The second photodiode SPD may operate in the HCG mode (i.e., the SPD-H mode) in a luminance section (e.g., a third luminance section), which has a higher luminance than the second luminance section, and may operate in the LCG mode (i.e., the SPD-L mode) in a luminance section (e.g., a fourth luminance section), which has a higher luminance than the third luminance section. The pixel PX1 may include the high-capacitance capacitor Cap, which may be connected to the second photodiode SPD to configure the pixel PX1 to decrease conversion gain when an exposure time is long in the fourth luminance section.

As described above, the pixel PX1 may achieve an HDR by operating in the HCG mode and the LCG mode with respect to each of the first photodiode LPD and the second photodiode SPD. For example, in each of the pixels PX of the pixel array 110, first image data generated when the first photodiode LPD operates in the HCG mode may be used to generate an image corresponding to the first luminance section (e.g., the darkest region), and second image data generated when the first photodiode LPD operates in the LCG mode may be used to generate an image corresponding to the second luminance section (e.g., a region that is brighter than the first luminance section). Third image data generated when the second photodiode SPD operates in the HCG mode may be used to generate an image corresponding to the third luminance section (e.g., a region that is brighter than the second luminance section and darker than the fourth luminance section), and fourth image data generated when the second photodiode SPD operates in the LCG mode may be used to generate an image corresponding to the fourth luminance section (e.g., the brightest region).

The first conversion gain transistor CGX may be connected between the first floating diffusion node FD1 and the second floating diffusion node FD2. The first conversion gain transistor CGX may be connected in series to the reset transistor RX through the second floating diffusion node FD2. The first conversion gain transistor CGX may change the conversion gain of the pixel PX1 by changing the capacitance of the first floating diffusion node FD1 in response to a first conversion gain control signal DGR1.

The first switching transistor SW may be connected between the second floating diffusion node FD2 and the third floating diffusion node FD3. The first switching transistor SW may change the conversion gain of the pixel PX1 by changing the capacitance of the third floating diffusion node FD3 in response to a first switching signal SWS.

The second conversion gain transistor TSW may be connected between the capacitor Cap (i.e., a charge storage element) and the third floating diffusion node FD3. The second conversion gain transistor TSW may change the conversion gain of the pixel PX1 by changing the capacitance of the third floating diffusion node FD3 in response to a second conversion gain control signal TSWS.

The pixel PX1 may include the capacitor Cap connected between the second conversion gain transistor TSW and a pixel power supply voltage VDDA. The pixel power supply voltage VDDA may also referred to herein interchangeably as a pixel power supply, a pixel voltage source, or the like. For example, the capacitor Cap may include a metal-oxide-semiconductor (MOS) capacitor, a metal-insulator-semiconductor (MIS) capacitor, or a metal-insulator-metal (MIM) capacitor. The capacitor Cap may store charges in response to the amount of charges generated by the second photodiode SPD and the operation of the second transfer transistor STX. The fourth floating diffusion node FD4 may be connected between the second conversion gain transistor TSW and the capacitor Cap.

The pixel PX1 may further include the second switching transistor DSW. The second switching transistor DSW may be connected to an end of the reset transistor RX and an end of the capacitor Cap. The second switching transistor DSW may be turned on in response to a second switching control signal DSWS, thereby adjusting the discharging speed of current flowing in the pixel PX1.

The reset transistor RX may be controlled by a reset signal RG and may periodically reset charges accumulated in the second floating diffusion node FD2 according to the reset signal RG. The drain terminal of the reset transistor RX may be connected to the second floating diffusion node FD2 and the source terminal of the reset transistor RX may be connected to the pixel power supply voltage VDDA. When the reset transistor RX is turned on, the pixel power supply voltage VDDA may be transmitted to the second floating diffusion node FD2. Accordingly, charges accumulated in the second floating diffusion node FD2 may be discharged such that the second floating diffusion node FD2 may be reset. According to on or off of the first conversion gain transistor CGX, the pixel power supply voltage VDDA may be transmitted to the first floating diffusion node FD1 and the first floating diffusion node FD1 may be reset. According to on or off the first conversion gain transistor CGX, the first switching transistor SW, and the second switching transistor DSW, the first to fourth floating diffusion nodes FD1, FD2, FD3, and FD4 may be reset.

The drive transistor SF may function as a source follower buffer amplifier that generates source-drain current in proportion to the amount of charges of the first floating diffusion node FD1, which are input to the gate electrode of the drive transistor SF. The drive transistor SF may amplify a potential change in the first floating diffusion node FD1 and may output an amplified signal as the output voltage V_OUT through the select transistor SX. The source terminal of the drive transistor SF may be connected to the pixel power supply voltage VDDA and the drain terminal of the drive transistor SF may be connected to the source terminal of the select transistor SX.

The select transistor SX may select a pixel that outputs the output voltage V_OUT. The select transistor SX may be turned on in response to a select control signal SEL, which is at an active level and applied to the gate terminal of the select transistor SX, and may output the output voltage V_OUT (or current) from the drain electrode of the drive transistor SF to a column line CL. The output voltage V_OUT may be provided to the ADC circuit 131 (in FIG. 1) through the column line CL.

According to some example embodiments, the conversion gain of the pixel PX1 may be adjusted by the first conversion gain transistor CGX, the first switching transistor SW, and the second conversion gain transistor TSW.

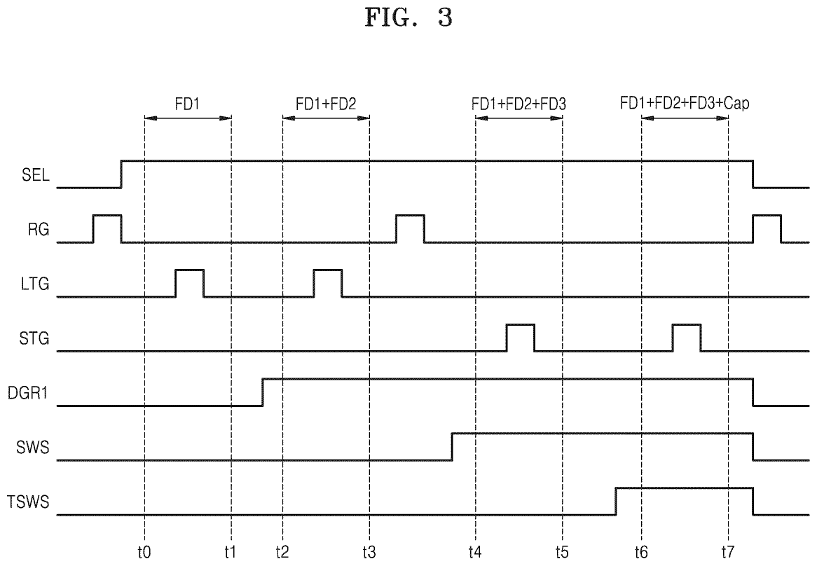

FIG. 3 is a timing diagram illustrating the operation of a pixel, according to some example embodiments. FIG. 3 is a timing diagram illustrating the operation of an image sensor including the pixel PX1 of FIG. 2.

Referring to FIGS. 2 and 3, in the operation of the image sensor, the reset signal RG may be activated and the reset transistor RX may be turned on. Accordingly, the pixel power supply voltage VDDA may be provided to the first floating diffusion node FD1 such that charges may be discharged from the first floating diffusion node FD1, thereby resetting (or initializing) the first floating diffusion node FD1.

When (e.g., based on) the reset signal RG is activated, the first conversion gain control signal DGR1 and the first switching control signal SWS may be activated and the pixel power supply voltage VDDA may be provided to the second and third floating diffusion nodes FD2 and FD3. Accordingly, the second and third floating diffusion nodes FD2 and FD3 may also be reset.

Subsequently, the reset signal RG may be inactivated and the reset transistor RX may be turned off. Accordingly, the first to third floating diffusion nodes FD1, FD2, and FD3 may be in a state in which charge accumulation is possible.

Immediately after the reset transistor RX is turned off, the select signal SEL may be activated and the select transistor SX may be turned on. When the select transistor SX is turned on, pixel signals may be output through the column line CL.

At a time point t0, a first reset signal, which is proportional to the potential of the first floating diffusion node FD1, may be output. After the first reset signal is read, the first transfer control signal LTG may be activated and the first transfer transistor LTX may be turned on. Accordingly, charges accumulated in the first photodiode LPD may be transferred to the first floating diffusion node FD1 in a first conversion gain mode CG1.

Subsequently, the first transfer control signal LTG may be inactivated and the first transfer transistor LTX may be turned off. At a time point t1, a first pixel signal, which is proportional to the amount of photocharges accumulated in the first photodiode LPD, may be output in the first conversion gain mode CG1.

After the first pixel signal is output, the first conversion gain control signal DGR1 may be activated and the first conversion gain transistor CGX may be turned on. Accordingly, the pixel PX1 may operate in a second conversion gain mode CG2 having a second conversion gain that is greater than a first conversion gain.

As the first conversion gain transistor CGX is turned on, the capacitance of the first floating diffusion node FD1 may increase to the sum of the capacitance of the first floating diffusion node FD1 and the capacitance of the second floating diffusion node FD2.

After the first conversion gain transistor CGX is turned on, a second reset signal, which is proportional to the potential of the first and second floating diffusion nodes FD1 and FD2, may be output at a time point t2.

After the second reset signal is read, the first transfer control signal LTG may be activated and the first transfer transistor LTX may be turned on. Accordingly, in the second conversion gain mode CG2, charges accumulated in the first photodiode LPD may be transferred to the first and second floating diffusion nodes FD1 and FD2.

Subsequently, the first transfer control signal LTG may be inactivated and the first transfer transistor LTX may be turned off. At a time point t3, a second pixel signal, which is proportional to the amount of photocharges accumulated in the first photodiode LPD, may be output in the second conversion gain mode CG2. In other words, the second pixel signal may be proportional to the amount of charges stored in the first and second floating diffusion nodes FD1 and FD2.

Subsequently, the reset signal RG may be activated and the reset transistor RX may be turned on. Accordingly, charges may be discharged from the first and second floating diffusion nodes FD1 and FD2 and the first and second floating diffusion nodes FD1 and FD2 may be reset.

After the first and second floating diffusion nodes FD1 and FD2 are reset, the first switching control signal SWS may be activated and the first switching transistor SW may be turned on. Accordingly, the pixel PX1 may operate in a third conversion gain mode CG3 having third conversion gain that is greater than the second conversion gain.

As the first conversion gain transistor CGX and the first switching transistor SW are turned on, the capacitance of the first floating diffusion node FD1 may increase to the sum of the capacitance of the first floating diffusion node FD1, the capacitance of the second floating diffusion node FD2, and the capacitance of the third floating diffusion node FD3.

After the first switching transistor SW is turned on, a third reset signal, which is proportional to the potential of the first to third floating diffusion nodes FD1, FD2, and FD3, may be output at a time point t4.

After the third reset signal is read, the second transfer control signal STG may be activated and the second transfer transistor STX may be turned on. Accordingly, in the third conversion gain mode CG3, charges accumulated in the second photodiode SPD may be transferred to the first to third floating diffusion nodes FD1, FD2, and FD3.

Subsequently, the second transfer control signal STG may be inactivated and the second transfer transistor STX may be turned off. At a time point t5, a third pixel signal, which is proportional to the amount of photocharges accumulated in the second photodiode SPD, may be output in the third conversion gain mode CG3. In other words, the third pixel signal may be proportional to the amount of charges stored in the first to third floating diffusion nodes FD1, FD2, and FD3.

After the third pixel signal is output, the second conversion gain control signal TSWS may be activated and the second conversion gain transistor TSW may be turned on. Accordingly, the pixel PX1 may operate in a fourth conversion gain mode CG4 having fourth conversion gain that is greater than the third conversion gain.

As the second conversion gain transistor TSW is turned on, the capacitance of the first floating diffusion node FD1 may increase to the sum of the capacitance of the first floating diffusion node FD1, the capacitance of the second floating diffusion node FD2, the capacitance of the third floating diffusion node FD3, and the capacitance of the capacitor Cap.

After the second conversion gain transistor TSW is turned on, a fourth reset signal, which is proportional to the potential of the first to third floating diffusion nodes FD1, FD2, and FD3 and the capacitor Cap, may be output at a time point t6.

After the fourth reset signal is read, the second transfer control signal STG may be activated and the second transfer transistor STX may be turned on. Accordingly, in the fourth conversion gain mode CG4, charges accumulated in the second photodiode SPD may be transferred to the first to third floating diffusion nodes FD1, FD2, and FD3 and the capacitor Cap.

Subsequently, the second transfer control signal STG may be inactivated and the second transfer transistor STX may be turned off. At a time point t7, a fourth pixel signal, which is proportional to the amount of photocharges accumulated in the second photodiode SPD, may be output in the fourth conversion gain mode CG4. In other words, the fourth pixel signal may be proportional to the amount of charges stored in the first to third floating diffusion nodes FD1, FD2, and FD3 and the capacitor Cap.

According to the inventive concepts, the third floating diffusion node FD3 may be connected to the fourth floating diffusion node FD4 to perform a readout operation of the second photodiode SPD in the fourth conversion gain mode CG4. According to some example embodiments, in an extremely high luminance region, overflowing charges may be integrated and stored in capacitor Cap and then read out. Here, because the third floating diffusion node FD3 and the fourth floating diffusion node FD4 continue storing charges during an accumulation time, FD leakage occurring in contacts respectively connected to the third floating diffusion node FD3 and the fourth floating diffusion node FD4 may continuously occur during the accumulation time and thus act as noise, which may manifest as noise in the output voltage V_OUT. In the HCG mode (the first conversion gain mode) and the LCG mode (the second conversion gain mode) of the first photodiode LPD and in the HCG mode (the third conversion gain mode) of the second photodiode SPD, charges may be accumulated in each of the first and second photodiodes LPD and SPD and read out, and accordingly, the influence of FD leakage is small. However, in the LCG mode (the fourth conversion gain mode) of the second photodiode SPD, charges may be accumulated in a floating diffusion node and a capacitor, and accordingly, the influence of FD leakage (e.g., upon noise and thus the quality of an image generated based on the output voltage V_OUT) may be significant during an accumulation period. Some example embodiments of the inventive concepts provide a layout of a pixel capable of reducing FD leakage.

FIG. 4A is a layout diagram of the pixel PX1 according to some example embodiments.

The pixel PX1 of FIG. 4A may correspond to the pixel PX1 of FIG. 2. The pixel PX1 of FIG. 4 may include a first pixel region 310 and a second pixel region 320. A first photoelectric conversion region 341 corresponding to the first photodiode LPD may be formed in the first pixel region 310. A second photoelectric conversion region 342 corresponding to the second photodiode SPD may be formed in the second pixel region 320. The first pixel region 310 may have a larger area (e.g., an area in the in-page plane of the plan view of FIG. 4A) than that of the second pixel region 320, and accordingly, the first photoelectric conversion region 341 may have a larger light-receiving area (e.g., an area in the in-page plane of the plan view of FIG. 4A) than that of the second photoelectric conversion region 342. According to some example embodiments, the first pixel region 310 may have an octagonal shape in a plan view and the second pixel region 320 may have a quadrangular shape in a plan view. However, the shapes of the first pixel region 310 and the second pixel region 320 may not be limited thereto.

Referring to FIG. 4A, along the octagonal shape of the first pixel region 310 in a plan view and the quadrangular shape of the second pixel region 320 in a plan view, a pixel isolation film 330 surrounding the first pixel region 310 and the second pixel region 320 may be provided to separate (e.g., isolate in the in-page plane of the plan view of FIG. 4A) the pixel PX1 from the surroundings. According to some example embodiments, the pixel isolation film 330 may include front deep trench isolation (FDTI).

Referring to FIG. 4A, the first pixel region 310 may be in contact with the second pixel region 320. The first pixel region 310 and the second pixel region 320 may be in contact with each other and thus share (e.g., contact opposite surfaces or sides of) a portion of the pixel isolation film 330. The first pixel region 310 and the second pixel region 320 may share (e.g., contact opposite surfaces or sides of) a first pixel isolation film 331 and a second pixel isolation film 332.

The first pixel isolation film 331 may be separated from (e.g., isolated from direct contact with) the second pixel isolation film 332. For example, the first pixel isolation film 331 may be isolated from direct contact with the second pixel isolation film 332 independently of other portions of the pixel isolation film 330, such that the first pixel isolation film 331 may be isolated from direct contact with the second pixel isolation film 332 independently of portions of the pixel isolation film 330 that are not shared between the first and second pixel regions 310 and 320. The first pixel isolation film 331 may be separated from the second pixel isolation film 332 by cutting a portion of the pixel isolation film 330, which corresponds to a central portion of a surface P (interchangeably referred to herein as a region) where the first pixel region 310 and the second pixel region 320 are in contact with each other. Due to the cutting structure in the portion of the pixel isolation film 330, which corresponds to the central portion of the surface P (portion P′) where the first pixel region 310 and the second pixel region 320 are in contact with each other, the first pixel region 310 and the second pixel region 320 may not be completely separated from each other. For example, the first and second pixel regions 310 and 320 may be exposed to each other through the central region (portion P′) that extends between, and is at least partially defined by opposing edges and/or surfaces of the first and second pixel isolation films 331 and 332. A plurality of transistors may be easily connected to each other by arranging a region (e.g., a structure) corresponding to the third floating diffusion node FD3 (e.g., a structure at least partially defining the third floating diffusion node FD3) in a region (portion P′) in which the first pixel region 310 and the second pixel region 320 are not completely separated from each other. The portion P′ may be at least partially defined between opposing surfaces and/or edges of the first and second pixel isolation films 331 and 332. The portion of the pixel isolation film 330, which corresponds to the central portion of the surface P, may be between the first pixel isolation film 331 and the second pixel isolation film 332 and may correspond to the region (portion P′). For example, the first and second pixel isolation films 331 and 332 may be separated from each other to at least partially define the portion P′ therebetween, where a region corresponding to the third floating diffusion node FD3 may extend across and/or between the first and second pixel regions 310 and 320 through the portion P′.

According to some example embodiments of the inventive concepts, due to the first pixel isolation film 331 and the second pixel isolation film 332 separated from (e.g., isolated from direct contact with) the first pixel isolation film 331, the first pixel region 310 and the second pixel region 320 may not be completely separated from each other. Because the region corresponding to the third floating diffusion node FD3 is arranged in the structure in which the portion of the pixel isolation film 330, which corresponds to the central portion P′ of the surface P where the first pixel region 310 and the second pixel region 320 are in contact with each other, is cut (e.g., such that the first and second pixel regions 310 and 320 may be exposed to each other from the pixel isolation film 330 through the central portion P′), a plurality of transistors connected to the third floating diffusion node FD3 may be arranged to be adjacent to each other, and regions respectively corresponding to the second floating diffusion node FD2, the third floating diffusion node FD3, and the fourth floating diffusion node FD4 may be connected to one another by adjusting a control signal applied to the transistors adjacent to each other.

Although it is illustrated in FIG. 4A that the first pixel isolation film 331 is separated from the second pixel isolation film 332 by the central portion P′ and the region corresponding to the central portion P′ is cut, the inventive concepts may not be limited thereto. In a pixel according to some example embodiments of the inventive concepts, the size of the first pixel isolation film 331 may not be the same as the size of the second pixel isolation film 332, and a region of the surface P that is not the region corresponding to the central portion P′ but instead is a region at one side of the surface P may be cut such that the first pixel isolation film 331 may be separated from the second pixel isolation film 332. For example one of the first pixel isolation film 331 or the second pixel isolation film 332 may have a null length in the in-page plane shown in FIG. 4, such that the portion P′ may be at least partially defined by one of the first pixel isolation film 331 or the second pixel isolation film and further at least partially defined by a portion of the pixel isolation film 330 that is not shared between the first and second pixel regions 310 and 320.

According to some example embodiments, a device isolation film may define an active portion ACT1 in the first and second pixel regions 310 and 320. For example, the active portion ACT1 may be provided to share (e.g., extend across, extend between, etc.) the first and second pixel regions 310 and 320. For example, a gate electrode of the second transfer transistor STX may be arranged in the active portion ACT1, and a gate electrode of the first switching transistor SW and a gate electrode of the second conversion gain transistor TSW may be arranged on the active portion ACT1 and separated from the gate electrode of the second transfer transistor STX. The region corresponding to the third floating diffusion node FD3 may be provided in the active portion ACTI among the gate electrode of the second transfer transistor STX, the gate electrode of the first switching transistor SW, and the gate electrode of the second conversion gain transistor TSW. For example, the active portion ACT1 may be formed between the first pixel isolation film 331 and the second pixel isolation film 332 (e.g., in the central portion P′). Here, an active portion may be an active region.

Referring back to FIG. 2, the transistors, i.e., the second conversion gain transistor TSW, the first switching transistor SW, and the second transfer transistor STX, which are connected to the third floating diffusion node FD3 are shown in FIG. 2. The second conversion gain transistor TSW, the first switching transistor SW, and the second transfer transistor STX may share the third floating diffusion node FD3.

Referring to FIG. 4A, the second photoelectric conversion region 342 and the second transfer transistor STX, which transfers charges generated in the second photoelectric conversion region 342 to the third floating diffusion node FD3, may be arranged in the second pixel region 320. The first switching transistor SW and the second conversion gain transistor TSW may be arranged in the first pixel region 310. The second conversion gain transistor TSW, the first switching transistor SW, and the second transfer transistor STX may be adjacent to the third floating diffusion node FD3 which is formed across (e.g., extends across, extends between, etc.) the first pixel region 310 and the second pixel region 320.

Referring to FIG. 4A, the drive transistor SX, the select transistor SF, the first conversion gain transistor CGX, the first transfer transistor LTX, the reset transistor RX, and the second switching transistor DSW may be arranged in the first pixel region 310. According to some example embodiments, the capacitor Cap may be further arranged in the second pixel region 320. According to some example embodiments, a ground GND may be arranged in the first pixel region 310. According to some example embodiments, the ground GND may be arranged in the second pixel region 320. The ground GND may be arranged in one of the first pixel region 310 or the second pixel region 320.

For convenience of description, contacts are omitted from FIG. 4A.

FIGS. 4B and 4C are cross-sectional views respectively taken along line A-A′ and line B-B′ in FIG. 4A according to some example embodiments.

FIG. 4B is a cross-sectional view taken along line A-A′ in FIG. 4A. Referring to FIG. 4B, a semiconductor substrate 301 may have a first surface 301a (or a front surface) and a second surface 301b (or a back surface) opposite to the first surface 301a. The semiconductor substrate 301 may be obtained by forming an epitaxial layer of a first conductivity type (e.g., p-type) on a bulk silicon substrate of the first conductivity type. The semiconductor substrate 301 may include a substrate in which only the p-type epitaxial layer remains after the bulk silicon substrate is removed during the process of manufacturing an image sensor. In some example embodiments, the semiconductor substrate 301 may include a bulk semiconductor substrate including a well of the first conductivity type.

The pixel isolation film 330 may be in the semiconductor substrate 301 and may define the first and second pixel regions 310 and 320. The pixel isolation film 330 may surround the first and second pixel regions 310 and 320 of the semiconductor substrate 301. However, in a region of the pixel isolation film 330 in which the first pixel region 310 is in contact with the second pixel region 320, a central portion of the pixel isolation film 330 may be cut.

According to some example embodiments, the pixel isolation film 330 may extend from the first surface 301a to the second surface 301b. The pixel isolation film 330 may be formed by forming a deep trench by patterning the first surface 301a of the semiconductor substrate 301 and filling the deep trench with a liner insulating film and an impurity-doped semiconductor film. In this case, the width of the pixel isolation film 330 (e.g., in a direction parallel to the first surface 301a and/or the second surface 301b) may decrease away from the first surface 301a of the semiconductor substrate 301 (e.g., in a direction perpendicular to the first surface 301a and/or the second surface 301b) and toward the second surface 301b of the semiconductor substrate 301. In some example embodiments, the width of the pixel isolation film 330 may be the same at both the first surface 301a and the second surface 301b of the semiconductor substrate 301.

In some example embodiments, the pixel isolation film 330 may be formed by forming a deep trench by patterning the second surface 301b of the semiconductor substrate 301 and filling the deep trench with a liner insulating film and an impurity-doped semiconductor film. In this case, the width of the pixel isolation film 330 may increase away from the first surface 301a of the semiconductor substrate 301 toward the second surface 301b of the semiconductor substrate 301.

The pixel isolation film 330 may include an insulating material that has a lower refractive index than the refractive index of the semiconductor substrate 301 (e.g., silicon) and may include one or more insulating films.

Referring to FIG. 4B, the second photoelectric conversion region 342 may be provided in a region of the semiconductor substrate 301 corresponding to the second pixel region 320. Incident light may be converted into an electrical signal in the second photoelectric conversion region 342.

The second photoelectric conversion region 342 may include an impurity region doped with impurities of a second conductivity type (e.g., an n-type), which is opposite to the semiconductor substrate 301 of the first conductivity type. The semiconductor substrate 301 of the first conductivity type and the second photoelectric conversion region 342 of the second conductivity type may form a photodiode.

Referring to FIG. 4B, in the second pixel region 320, a gate electrode STX_G of the second transfer transistor STX may be on the first surface 301a of the semiconductor substrate 301. In the semiconductor substrate 301, a third floating diffusion region FD3_A may be at one side of the gate electrode STX_G of the second transfer transistor STX.

According to some example embodiments, a portion of the gate electrode STX_G of the second transfer transistor STX may be arranged in a trench formed by recessing the first surface 301a of the semiconductor substrate 301, and a gate insulating film may be between the gate electrode STX_G and the semiconductor substrate 301. In some example embodiments, the shape and the position of the gate electrode STX_G may vary.

Referring to FIG. 4B, the third floating diffusion region FD3_A may include an n-type impurity region formed by doping the semiconductor substrate 301 with impurities of a conductivity type opposite to the semiconductor substrate 301. Here, an n-th floating diffusion region may refer to an impurity region corresponding to an n-th floating diffusion node. Here, “n” is a natural number of at least 1. The third floating diffusion region FD3_A may be arranged in a region shared by both the first pixel region 310 and the second pixel region 320. For example, as shown, the third floating diffusion region FD3_A may extend across (e.g., may extend between) the first pixel region 310 and the second pixel region 320, such that the third floating diffusion region FD3_A is in both the first and second pixel regions 310 and 320. Accordingly, an element in the first pixel region 310 may be connected (e.g., electrically connected via the third floating diffusion region FD3_A corresponding to the third floating diffusion node FD3) to an element in the second pixel region 320, and unnecessary contacts may be eliminated.

Referring to FIG. 4B, a color filter CF may be formed in correspondence to a pixel region. According to some example embodiments, the first and second pixel regions 310 and 320 may share one color filter (e.g., both the first and second pixel regions 310 and 320 may overlap one color filter in a direction perpendicular to the first surface 301a and/or the second surface 301b). The first and second photoelectric conversion regions 341 and 342 may each convert light, which passes through the color filter CF, into an electrical signal. The color filter CF may include a red, green, or blue color filter or a magenta, cyan, or yellow color filter. For example, the color filter may include a white color filter or an infrared filter.

Microlenses ML1 and ML2 may each have a convex shape and a certain radius of curvature. The microlenses ML1 and ML2 may be arranged on the color filter CF in correspondence to the first and second pixel regions 310 and 320, respectively.

The sum of light-receiving areas of photodiodes in the first pixel region 310 may be larger than the light-receiving area of a photodiode in the second pixel region 320, and accordingly, the area of the microlens ML1 in the first pixel region 310 may be larger than the area of the microlens ML2 in the second pixel region 320. The radius of curvature of the microlens ML1 in the first pixel region 310 may be different from the radius of curvature of the microlens ML2 in the second pixel region 320.

The cross-sectional view of FIG. 4B is a simplified illustration, and an interlayer insulating film, a wiring structure, a contact plug, etc. are omitted for convenience of description.

FIG. 4C is a cross-sectional view taken along line B-B′ in FIG. 4A. Redundant descriptions given with reference to FIG. 4B are omitted from the descriptions of FIG. 4C.

FIG. 4C shows gates of a plurality of transistors and floating diffusion regions adjacent to the gates of the transistors in the first pixel region 310. The third floating diffusion region FD3_A, a second floating diffusion region FD2_A, and a fourth floating diffusion region FD4_A may be formed in the semiconductor substrate 301. According to some example embodiments, the third floating diffusion region FD3_A, the second floating diffusion region FD2_A, and the fourth floating diffusion region FD4_A may each include an n-type impurity region that is formed by doping the semiconductor substrate 301 with impurities of a conductivity type opposite to the conductivity type of the semiconductor substrate 301. A gate electrode SW_G of the first switching transistor SW and a gate electrode TSW_G of the second conversion gain transistor TSW may be formed on the first surface 301a of the semiconductor substrate 301.

FIGS. 4B and 4C show gate electrodes (e.g., SW_G, TSW_G, and STX_G) adjacent to the third floating diffusion region FD3_A. In other words, when the gate electrodes (SW_G, TSW_G, and STX_G) are turned on, the second floating diffusion region FD2_A may be connected to the fourth floating diffusion region FD4_A through the third floating diffusion region FD3_A. A contact CA vertically extending may be connected to the fourth floating diffusion region FD4_A.

An interlayer insulating film 350 surrounding the contact CA may be arranged on the first surface 301a of the semiconductor substrate 301. The interlayer insulating film 350 may cover transistors and gate electrodes, which form a readout circuit, and may include a plurality of insulating films. For example, the interlayer insulating film 350 may include silicon oxide, silicon nitride, and/or silicon oxynitride.

According to the inventive concepts, only one contact may be necessary for the operation of a pixel, compared to the number of contacts of floating diffusion nodes according to a structure in which a first pixel region and a second pixel region are completely separated from each other in a comparative embodiment. As a result, FD leakage may be reduced and the freedom of a layout may be secured.

According to the inventive concepts, the central portion of the pixel isolation film 330, which separates the first pixel region 310 from the second pixel region 320, may be cut such that the first pixel region 310 may be connected to the second pixel region 320 by using a floating diffusion region as a junction. Accordingly, the number (quantity) of contacts causing FD leakage may be reduced, and noise may be improved. As a result, a signal-to-noise ratio (SNR) dip may be reduced and dark noise may be improved during a readout operation in the LCG mode of the second photodiode SPD.

Although the third floating diffusion node FD3 is shared by the first pixel region 310 from the second pixel region 320 in the example embodiments shown in FIGS. 4A-4C, the inventive concepts are not limited thereto. It should be noted that the inventive concepts may be applied to any configuration in which a floating diffusion node is shared by different pixel regions to connect the different pixel regions to each other.

The layout structure of a pixel according to the inventive concepts may be applied to any pixel that has a split photodiode structure in image sensors. The inventive concepts may be applied to any sensor pixels for automobiles and mobile devices.

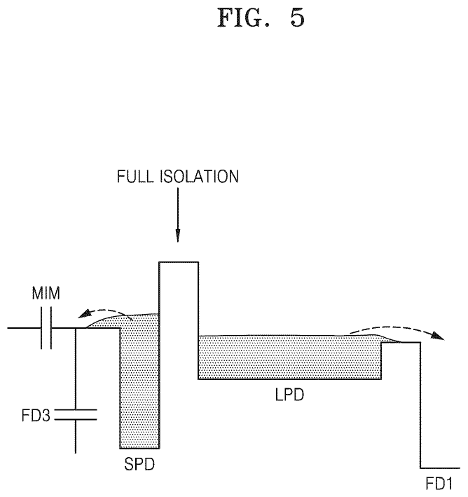

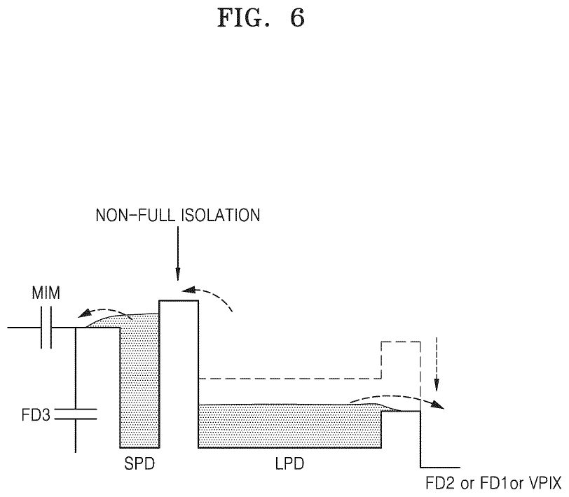

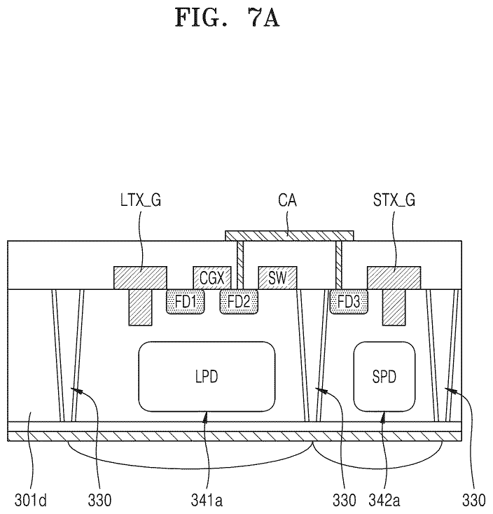

FIG. 5 is a potential diagram of a pixel according to a comparative embodiment. FIG. 6 is a potential diagram of a pixel according to the inventive concepts.

FIG. 5 illustrates the potential of the second photodiode SPD and the potential of the first photodiode LPD in the layout structure of a pixel according to the comparative example. In the pixel according to the comparative embodiment, a region in which the first photodiode LPD is arranged may be physically fully isolated from a region in which the second photodiode SPD is arranged, and therefore, the likelihood of overflow of charges from a pixel region to another pixel region may be significantly low.

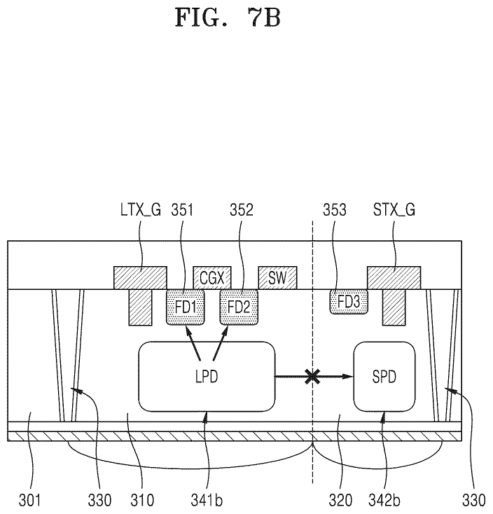

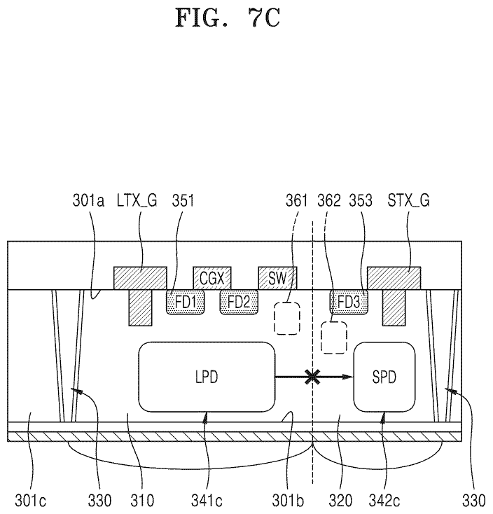

FIG. 6 illustrates the potential of the second photodiode SPD and the potential of the first photodiode LPD in the layout structure of a pixel according to the inventive concepts. In the layout structure of a pixel according to the inventive concepts, a region in which the first photodiode LPD is arranged may not be physically fully isolated from a region in which the second photodiode SPD is arranged. Accordingly, when high-luminance light is incident to an image sensor, charges generated in the first photodiode LPD may flow over the potential barrier of a first pixel region including the first photodiode LPD into a second pixel region including the second photodiode SPD while a pixel signal proportional to the amount of photocharges accumulated in the second photodiode SPD is being output. As described above, overflowing charges may distort the pixel signal output from the second photodiode SPD. The inventive concepts provide the structures of FIGS. 7B and 7C to prevent charges from overflowing from one pixel region into another pixel region, or to reduce or minimize such overflow.

FIG. 7A is a diagram illustrating the flow of charges in a pixel according to a comparative embodiment and FIGS. 7B and 7C are diagrams illustrating the flow of charges in a pixel according to some example embodiments of the inventive concepts.

FIG. 7A shows a first photoelectric conversion region 341a and a second photoelectric conversion region 342a, which are formed in a semiconductor substrate 301d. In embodiments, the light-receiving area of the first photoelectric conversion region 341a may be larger than the light-receiving area of the second photoelectric conversion region 342a. In other words, the volume of the first photoelectric conversion region 341a may be larger than the volume of the second photoelectric conversion region 342a. According to some example embodiments, the first photoelectric conversion region 341a may have a first width in one direction and the second photoelectric conversion region 342a may have a second width in one direction, wherein the second width may be less than the first width. The first and second photoelectric conversion regions 341a and 342a may have substantially the same vertical depth.

According to the comparative embodiment, each of the first and second photoelectric conversion regions 341a and 342a may be surrounded (e.g., entirely surrounded) by the pixel isolation film 330 in a plan view. To isolate a first photocharge packet generated by the first photodiode LPD from a second photocharge packet generated by the second photodiode SPD, pixel regions respectively corresponding to the first and second photoelectric conversion regions 341a and 342a may be separated by the pixel isolation film 330 from each other.

According to the comparative embodiment, due to the first photodiode LPD and the second photodiode SPD that are physically separated from each other, contacts may be formed to connect floating diffusion nodes respectively connected to the first and second photodiodes LPD and SPD and then connected by a metal layer. At this time, in the LCG mode of the second photodiode SPD, charges may be accumulated in the floating diffusion nodes, and noise degradation (e.g., noise degradation in output signals generated by the pixel) may occur due to a plurality of contacts.

Referring to FIG. 7B, in some example embodiments, to prevent (or reduce or minimize) overflowing charges of the first photodiode LPD corresponding to a first photoelectric conversion region 341b in the first pixel region 310 from affecting the second photodiode SPD corresponding to a second photoelectric conversion region 342b in the second pixel region 320, an impurity concentration in a first floating diffusion region 351 and/or a second floating diffusion region 352 may be increased. According to some example embodiments, an n-type impurity concentration in the first floating diffusion region 351 and/or the second floating diffusion region 352 may be increased to secure an overflow path through a junction. According to some example embodiments, an n-type impurity doping concentration in the first floating diffusion region 351 and/or the second floating diffusion region 352 may be higher than an n-type impurity doping concentration in a third floating diffusion region 353.

Referring to FIG. 7C, in some example embodiments, to prevent (or reduce or minimize) overflowing charges of the first photodiode LPD in the first pixel region 310 from affecting the second photodiode SPD in the second pixel region 320, a first well impurity region 361 and a second well impurity region 362 may be respectively added to the first pixel region 310 and the second pixel region 320. The first and second well impurity regions 361 and 362 may be formed by doping a semiconductor substrate 301c with impurities of the first conductivity type.

According to some example embodiments, the first well impurity region 361 may be provided in the semiconductor substrate 301c not to overlap the first floating diffusion region 351 (e.g., to not entirely overlap the first floating diffusion region 351 in a vertical direction perpendicular to the first surface 301a and/or the second surface 301b of the semiconductor substrate 301c and/or to not entirely overlap the first floating diffusion region 351 in a horizontal direction parallel to the first surface 301a and/or the second surface 301b), and the second well impurity region 362 may be provided in the semiconductor substrate 301c not to overlap the third floating diffusion region 353 (e.g., to not entirely overlap the third floating diffusion region 353 in a vertical direction perpendicular to the first surface 301a and/or the second surface 301b of the semiconductor substrate 301c and/or to not entirely overlap the third floating diffusion region 353 in a horizontal direction parallel to the first surface 301a and/or the second surface 301b).

When viewed in the vertical direction, the first well impurity region 361 may be located among a first photoelectric conversion region 341c and the first and second floating diffusion nodes FD1 and FD2. The first well impurity region 361 may provide a potential barrier among the first photoelectric conversion region 341c and the first and second floating diffusion nodes FD1 and FD2. Accordingly, the overflow of charges may be prevented.

When viewed in the vertical direction, the second well impurity region 362 may be located between a second photoelectric conversion region 342c and the third floating diffusion node FD3. The second well impurity region 362 may provide a potential barrier between the second photoelectric conversion region 342c and the third floating diffusion node FD3. Accordingly, the overflow of charges may be prevented.

The overflow paths described above are just examples, and various methods of forming an overflow path may be used.

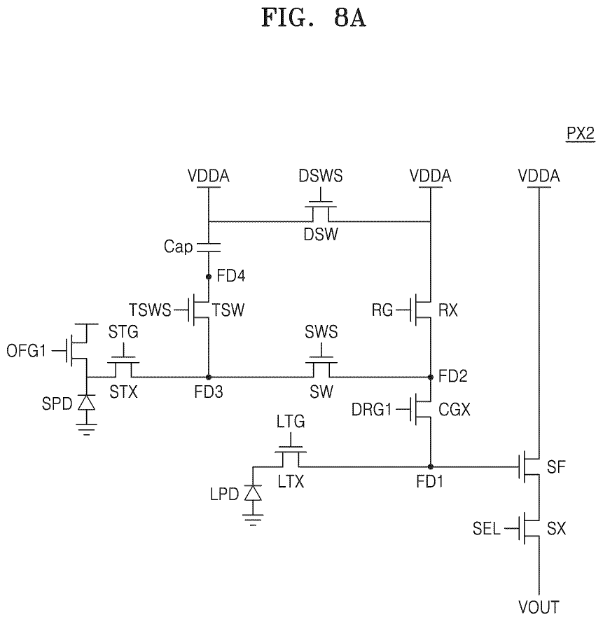

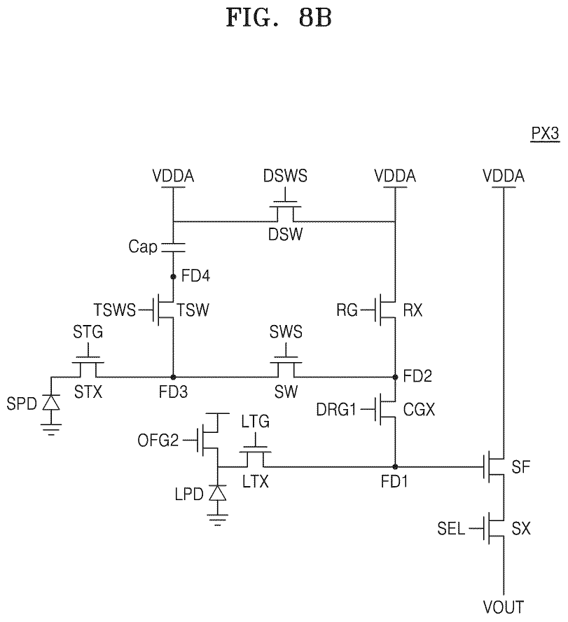

FIGS. 8A and 8B are circuit diagrams of pixels according to some example embodiments. In the circuit diagrams of FIGS. 8A and 8B, redundant descriptions of the same elements as those illustrated in the circuit diagram of FIG. 2 are omitted.

Compared to the pixel PX1 of FIG. 2, a pixel PX2 of FIG. 8A according to some example embodiments may further include a first overflow gate transistor OFG1 connected in series to the second photodiode SPD. Compared to the pixel PX1 of FIG. 2, a pixel PX3 of FIG. 8B according to some example embodiments may further include a second overflow gate transistor OFG2 connected in series to the first photodiode LPD. According to some example embodiments, the first overflow gate transistor OFG1 may be controlled by a first overflow signal and may prevent an overflow (or reduce or minimize such overflow) by controlling the path of charges flowing out due to the overflow of the second photodiode SPD. According to some example embodiments, the second overflow gate transistor OFG2 may be controlled by a second overflow signal and may prevent an overflow (or reduce or minimize such overflow) by controlling the path of charges flowing out due to the overflow of the first photodiode LPD.

According to some example embodiments, as shown in FIGS. 8A and 8B, a pixel may include an overflow gate transistor that provides a path for preventing an overflow, thereby controlling charges such that they do not cross over the potential barrier of a photodiode.

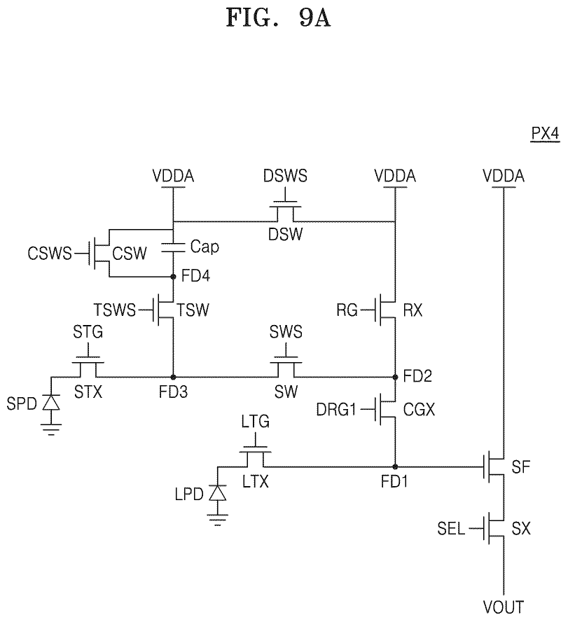

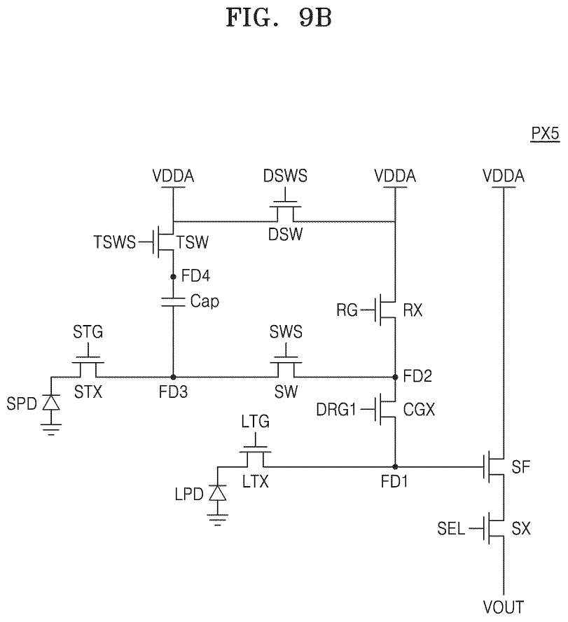

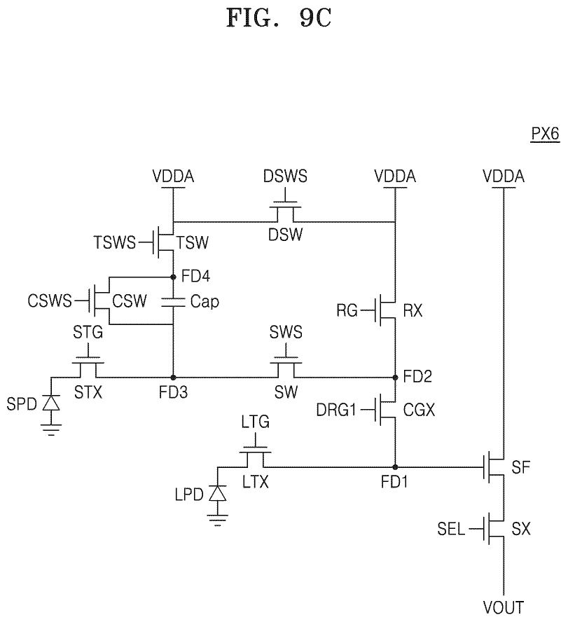

FIGS. 9A, 9B, and 9C are circuit diagrams of pixels according to some example embodiments. In the circuit diagrams of FIGS. 9A to 9C, redundant descriptions of the same elements as those illustrated in the circuit diagram of FIG. 2 are omitted.

Compared to the pixel PX1 of FIG. 2, a pixel PX4 of FIG. 9A according to some example embodiments may further include a third switching transistor CSW connected in parallel to the capacitor Cap. An end of the third switching transistor CSW may be connected to the fourth floating diffusion node FD4 and the opposite end of the third switching transistor CSW may be connected to the pixel power supply voltage VDDA. The third switching transistor CSW may be turned on based on a third switching control signal CSWS and may influence the capacitance of the fourth floating diffusion node FD4.

In a pixel PX5 of FIG. 9B according to some example embodiments, the capacitor Cap may be between the third floating diffusion node FD3 and the fourth floating diffusion node FD4, and the second conversion gain transistor TSW may be between the fourth floating diffusion node FD4 and the pixel power supply voltage VDDA. Compared to some example embodiments, including the example embodiments shown in FIG. 2, the position of the capacitor Cap and the position of the second conversion gain transistor TSW may be reversed.

In a pixel PX6 of FIG. 9C according to some example embodiments, the capacitor Cap may be between the third floating diffusion node FD3 and the fourth floating diffusion node FD4, and the second conversion gain transistor TSW may be between the fourth floating diffusion node FD4 and the pixel power supply voltage VDDA. Compared to the pixel PX1 of FIG. 2, the pixel PX6 of FIG. 9C may further include the third switching transistor CSW connected in parallel to the capacitor Cap. Compared to some example embodiments, including the example embodiments shown in FIG. 9A, the position of the capacitor Cap and the third switching transistor CSW and the position of the second conversion gain transistor TSW may be reversed.

As described above, the positions of a plurality of transistors of a pixel may be variously changed, and the layout structure of the inventive concepts may also be applied to the changed circuit structures.

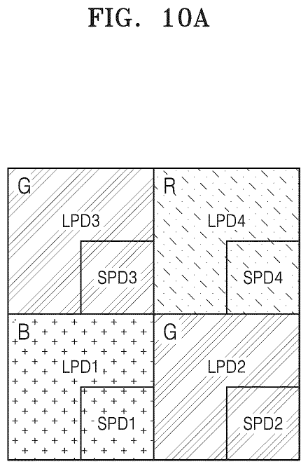

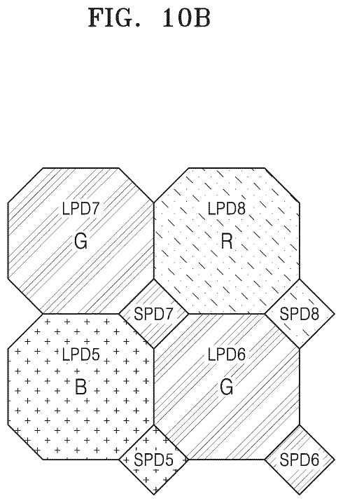

FIGS. 10A and 10B are diagrams illustrating the arrangements of pixels according to some example embodiments.

FIG. 10A shows a configuration in which first pixel regions LPD1, LPD2, LPD3, and LPD4 each corresponding to a first photodiode and second pixel regions SPD1, SPD2, SPD3, and SPD4 each corresponding to a second photodiode are arranged in a Bayer pattern. The second pixel regions SPD1, SPD2, SPD3, and SPD4 each corresponding to a second photodiode may each have a quadrangular shape in a plan view. The first pixel regions LPD1, LPD2, LPD3, and LPD4 each corresponding to a first photodiode may each have an L shape in a plan view. One of the first pixel regions LPD1, LPD2, LPD3, or LPD4 each corresponding to a first photodiode and one of the second pixel regions SPD1, SPD2, SPD3, or SPD4 each corresponding to a second photodiode may be combined into a quadrangular shape in a plan view and may form a pixel corresponding to one of the colors in the Bayer pattern. The central portion of a region in which the first pixel region (e.g., LPD1) and the second pixel region (e.g., SPD1), which correspond to one color in the Bayer pattern, are in contact with each other may be cut and open, and a region corresponding to a floating diffusion node may be arranged in the cut and open central portion.

FIG. 10B shows a configuration in which first pixel regions LPD5, LPD6, LPD7, and LPD8 each corresponding to a first photodiode and second pixel regions SPD5, SPD6, SPD7, and SPD8 each corresponding to a second photodiode are arranged in a Bayer pattern. The second pixel regions SPD5, SPD6, SPD7, and SPD8 each corresponding to a second photodiode may each have a quadrangular shape in a plan view. The first pixel regions LPD5, LPD6, LPD7, and LPD8 each corresponding to a first photodiode may each have an octagonal shape in a plan view. The first pixel regions LPD5, LPD6, LPD7, and LPD8 and the second pixel regions SPD5, SPD6, SPD7, and SPD8 may alternate in diagonal directions. Each of the second pixel regions SPD5, SPD6, SPD7, and SPD8 may be between two of the first pixel regions LPD5, LPD6, LPD7, and LPD8 in a diagonal direction.

One of the first pixel regions LPD5, LPD6, LPD7, or LPD8 each corresponding to a first photodiode and one of the second pixel regions SPD5, SPD6, SPD7, or SPD8 each corresponding to a second photodiode may be combined into a pixel corresponding to one of the colors in the Bayer pattern. The central portion of a region in which the first pixel region (e.g., LPD5) and the second pixel region (e.g., SPD5), which correspond to one color in the Bayer pattern, are in contact with each other may be cut and open, and a region corresponding to a floating diffusion node may be arranged in the cut and open central portion.

The arrangements illustrated in FIGS. 10A and 10B are just examples, and pixels according to the inventive concepts may correspond to various color patterns, and the shape of a first pixel region and the shape of a second pixel region may vary.

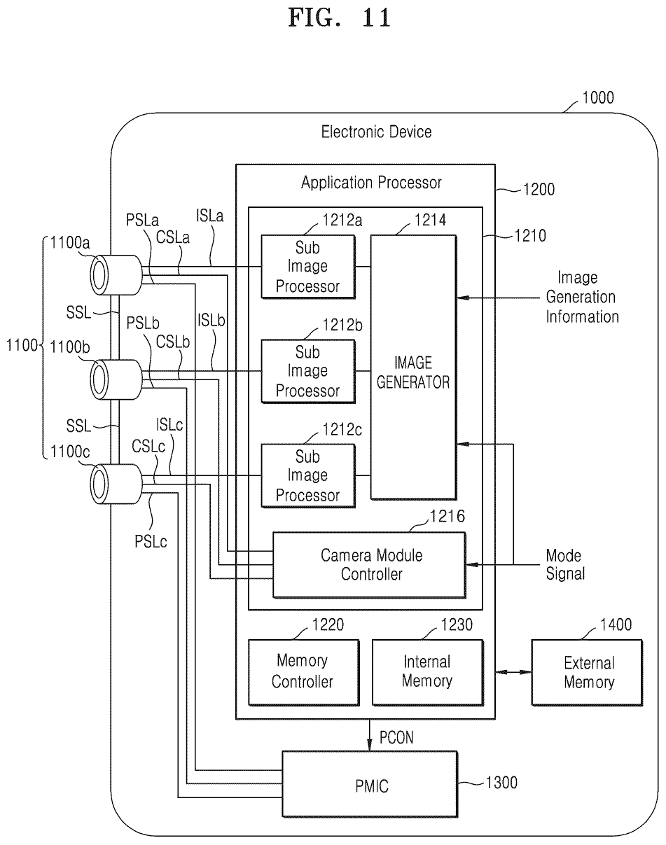

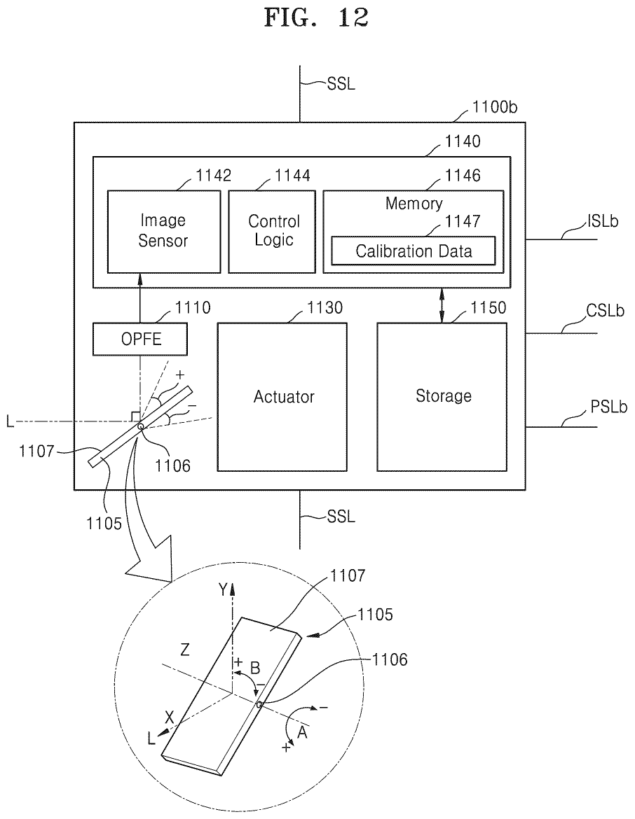

FIG. 11 is a block diagram of an electronic device including multiple camera modules. FIG. 12 is a detailed block diagram of a camera module in FIG. 11.

Referring to FIG. 11, an electronic device 1000 may include a camera module group 1100, an application processor 1200, a power management integrated circuit (PMIC) 1300, and an external memory 1400.

The camera module group 1100 may include a plurality of camera modules 1100a, 1100b, and 1100c. Although three camera modules 1100a, 1100b, and 1100c are illustrated in FIG. 11, example embodiments are not limited thereto. In some example embodiments, the camera module group 1100 may be modified to include only two camera modules. In some example embodiments, the camera module group 1100 may be modified to include “k” camera modules, where “k” is a natural number of at least 4.

The detailed configuration of the camera module 1100b is described with reference to FIG. 12 below. The descriptions below may also be applied to the other camera modules 1100a and 1100c.

Referring to FIG. 12, the camera module 1100b may include a prism 1105, an optical path folding element (OPFE) 1110, an actuator 1130, an image sensing device 1140, and a storage 1150.

The prism 1105 may include a reflective surface 1107 of a light reflecting material and may change the path of light L incident from outside.

In some example embodiments, the prism 1105 may change the path of the light L incident in a first direction X into a second direction Y perpendicular to the first direction X. The prism 1105 may rotate the reflective surface 1107 of the light reflecting material in a direction A around a central shaft 1106 or rotate the central shaft 1106 in a direction B so that the path of the light L incident in the first direction X is changed into the second direction Y perpendicular to the first direction X. At this time, the OPFE 1110 may move in a third direction Z, which is perpendicular to the first and second directions X and Y.

In some example embodiments, an A-direction maximum rotation angle of the prism 1105 may be less than or equal to 15 degrees in a plus (+) A direction and greater than 15 degrees in a minus (−) A direction, but embodiments are not limited thereto.

In some example embodiments, the prism 1105 may move by an angle of about 20 degrees or in a range from about 10 degrees to about 20 degrees or from about 15 degrees to about 20 degrees in a plus or minus B direction. At this time, an angle by which the prism 1105 moves in the plus B direction may be the same as or similar, within a difference of about 1 degree, to an angle by which the prism 1105 moves in the minus B direction.

In some example embodiments, the prism 1105 may move the reflective surface 1107 of the light reflecting material in the third direction Z parallel with an extension direction of the central shaft 1106.

The OPFE 1110 may include, for example, “m” optical lenses, where “m” is a natural number. The “m” lenses may move in the second direction Y and change an optical zoom ratio of the camera module 1100b. For example, when the default optical zoom ratio of the camera module 1100b is Z, the optical zoom ratio of the camera module 1100b may be changed to 3 Z, 5 Z, or greater by moving the “m” optical lenses included in the OPFE 1110.

The actuator 1130 may move the OPFE 1110 (or an optical lens) (hereinafter, referred to as an optical lens) to a certain position. For example, the actuator 1130 may adjust the position of the optical lens such that an image sensor 1142 is at a focal length of the optical lens for accurate sensing.

The image sensing device 1140 may include the image sensor 1142, a control logic 1144, and a memory 1146. The image sensor 1142 may sense an image of an object by using the light L provided through the optical lens. A pixel included in the image sensor 1142 may include a split photodiode including a plurality of photodiodes and which may be a pixel according to one or more of the example embodiments, including for example one or more of pixels having some or all of the structures shown in FIGS. 4A-4C, 7B-7C, 8A-8B, and/or 9A-9C. The split photodiode may include a large photodiode, which has a relatively large light-receiving area, and a small photodiode, which has a relatively small light-receiving area. Pixel regions, in which the large photodiode and the small photodiode are respectively arranged, may not be physically fully isolated from each other and may share a floating diffusion region, and accordingly, the number of contacts may be reduced. As a result, one or more of the pixels of image sensor 1142 may be configured to generate output signals with reduced noise degradation due to the reduced number of contacts, and/or the freedom of internal layout of elements of the pixels may be improved, based on the pixel regions of the pixels not being physically fully isolated from each other and sharing a floating diffusion region.

The control logic 1144 may generally control operations of the camera module 1100b. For example, the control logic 1144 may control operation of the camera module 1100b, according to a control signal provided through a control signal line CSLb.

The memory 1146 may store information, such as calibration data 1147, necessary for the operation of the camera module 1100b. The calibration data 1147 may include information, which is necessary for the camera module 1100b to generate image data using the light L provided from outside. For example, the calibration data 1147 may include information about the degree of rotation described above, information about a focal length, information about an optical axis, or the like. When the camera module 1100b is implemented as a multi-state camera that has a focal length varying with the position of the optical lens, the calibration data 1147 may include a value of a focal length for each position (or state) of the optical lens and information about auto focusing.

The storage 1150 may store image data sensed by the image sensor 1142. The storage 1150 may be provided outside the image sensing device 1140 and may form a stack with a sensor chip of the image sensing device 1140. In some example embodiments, the storage 1150 may include electrically erasable programmable read-only memory (EEPROM), but embodiments are not limited thereto.

Referring to FIGS. 11 and 12, in some example embodiments, each of the camera modules 1100a, 1100b, and 1100c may include the actuator 1130. Accordingly, the camera modules 1100a, 1100b, and 1100c may include the calibration data 1147, which is the same or different among the camera modules 1100a, 1100b, and 1100c according to the operation of the actuator 1130 included in each of the camera modules 1100a, 1100b, and 1100c.

In some example embodiments, one (e.g., the camera module 1100b) of the camera modules 1100a, 1100b, and 1100c may be of a folded-lens type including the prism 1105 and the OPFE 1110 while the other camera modules (e.g., the camera modules 1100a and 1100c) may be of a vertical type that does not include the prism 1105 and the OPFE 1110. However, example embodiments are not limited thereto.

In some example embodiments, one (e.g., the camera module 1100c) of the camera modules 1100a, 1100b, and 1100c may include a vertical depth camera, which extracts depth information using an infrared ray (IR). In this case, the application processor 1200 may generate a three-dimensional (3D) depth image by merging image data provided from the depth camera with image data provided from another camera module (e.g., the camera module 1100a or 1100b).

In some example embodiments, at least two camera modules (e.g., 1100a and 1100b) among the camera modules 1100a, 1100b, and 1100c may have different field-of-views. In this case, the two camera modules (e.g., 1100a and 1100b) among the camera modules 1100a, 1100b, and 1100c may respectively have different optical lenses, but embodiments are not limited thereto.

In some example embodiments, the camera modules 1100a, 1100b, and 1100c may have different field-of-views from one another. In this case, the camera modules 1100a, 1100b, and 1100c may respectively have different optical lenses, but embodiments are not limited thereto.

In some example embodiments, the camera modules 1100a, 1100b, and 1100c may be physically separated from one another. In other words, the sensing area of the image sensor 1142 is not divided and used by the camera modules 1100a, 1100b, and 1100c, but the image sensor 1142 may be independently included in each of the camera modules 1100a, 1100b, and 1100c.

Referring back to FIG. 11, the application processor 1200 may include an image processing unit 1210, a memory controller 1220, and an internal memory 1230. The application processor 1200 may be separately implemented from the camera modules 1100a, 1100b, and 1100c. For example, the application processor 1200 may be implemented in a different semiconductor chip than the camera modules 1100a, 1100b, and 1100c.

The image processing unit 1210 may include a plurality of sub image processors 1212a, 1212b, and 1212c, an image generator 1214, and a camera module controller 1216.

The image processing unit 1210 may include as many sub image processors 1212a, 1212b, and 1212c as the camera modules 1100a, 1100b, and 1100c.

Pieces of image data respectively generated from the camera modules 1100a, 1100b, and 1100c may be respectively provided to the sub image processors 1212a, 1212b, and 1212c respectively through image signal lines ISLa, ISLb, and ISLc, which are separated from one another. For example, image data generated from the camera module 1100a may be provided to the sub image processor 1212a through the image signal line ISLa, image data generated from the camera module 1100b may be provided to the sub image processor 1212b through the image signal line ISLb, and image data generated from the camera module 1100c may be provided to the sub image processor 1212c through the image signal line ISLc. Such image data transmission may be performed using, for example, a mobile industry processor interface (MIPI)-based camera serial interface (CSI), but embodiments are not limited thereto.

In some example embodiments, a single sub image processor may be provided for a plurality of camera modules. For example, differently from FIG. 11, the sub image processors 1212a and 1212c may not be separate from each other but may be integrated into a single sub image processor, and the image data provided from the camera module 1100a or the camera module 1100c may be selected by a selection element (e.g., a multiplexer) and then provided to the integrated sub image processor.

The image data provided to each of the sub image processors 1212a, 1212b, and 1212c may be provided to the image generator 1214. The image generator 1214 may generate an output image using the image data provided from each of the sub image processors 1212a, 1212b, and 1212c according to image generation information or a mode signal.

In detail, the image generator 1214 may generate the output image by merging at least portions of respective pieces of image data, which are respectively generated from the camera modules 1100a, 1100b, and 1100c having different field-of-views, according to the image generation information or the mode signal. In some example embodiments, the image generator 1214 may generate the output image by selecting one of pieces of image data, which are respectively generated from the camera modules 1100a, 1100b, and 1100c having different field-of-views, according to the image generation information or the mode signal.

In some example embodiments, the image generation information may include a zoom signal or a zoom factor. In some example embodiments, the mode signal may be based on a mode selected by a user.

When the image generation information includes a zoom signal or a zoom factor and the camera modules 1100a, 1100b, and 1100c have different field-of-views, the image generator 1214 may perform different operations according to different kinds of zoom signals. For example, when the zoom signal is a first signal, the image generator 1214 may merge image data output from the camera module 1100a and image data output from the camera module 1100c into a merged image signal and generate an output image using the merged image data and image data, which is output from the camera module 1100b and is not used in the merging. When the zoom signal is a second signal different from the first signal, the image generator 1214 may generate an output image by selecting one of the pieces of image data respectively output from the camera modules 1100a, 1100b, and 1100c, instead of performing the merging. However, example embodiments are not limited thereto, and a method of processing image data may be changed whenever necessary.

The camera module controller 1216 may provide a control signal to each of the camera modules 1100a, 1100b, and 1100c. A control signal generated by the camera module controller 1216 may be provided to its corresponding one of the camera modules 1100a, 1100b, and 1100c through its corresponding one of control signal lines CSLa, CSLb, and CSLc, which are separate from one another.

One (e.g., the camera module 1100b) of the camera modules 1100a, 1100b, and 1100c may be designated as a master camera according to the mode signal or the image generation signal including a zoom signal, and the other camera modules (e.g., 1100a and 1100c) may be designated as slave cameras. Such designation information may be included in a control signal and provided to each of the camera modules 1100a, 1100b, and 1100c through its corresponding one of control signal lines CSLa, CSLb, and CSLc, which are separate from one another.

A camera module operating as a master or a slave may be changed according to a zoom factor or an operation mode signal. For example, when the field-of-view of the camera module 1100a is greater than that of the camera module 1100b and the zoom factor indicates a low zoom ratio, the camera module 1100b may operate as a master and the camera module 1100a may operate as a slave. Contrarily, when the zoom factor indicates a high zoom ratio, the camera module 1100a may operate as a master and the camera module 1100b may operate as a slave.

In some example embodiments, a control signal provided from the camera module controller 1216 to each of the camera modules 1100a, 1100b, and 1100c may include a sync enable signal. For example, when the camera module 1100b is a master camera and the camera modules 1100a and 1100c are slave cameras, the camera module controller 1216 may transmit the sync enable signal to the camera module 1100b. The camera module 1100b provided with the sync enable signal may generate a sync signal based on the sync enable signal and may provide the sync signal to the camera modules 1100a and 1100c through a sync signal line SSL. The camera modules 1100a, 1100b, and 1100c may be synchronized with the sync signal and may transmit image data to the application processor 1200.

In some example embodiments, a control signal provided from the camera module controller 1216 to each of the camera modules 1100a, 1100b, and 1100c may include mode information according to the mode signal. The camera modules 1100a, 1100b, and 1100c may operate in a first operation mode or a second operation mode in relation to a sensing speed, based on the mode information.

In the first operation mode, the camera modules 1100a, 1100b, and 1100c may generate an image signal at a first speed (e.g., at a first frame rate), encode the image signal at a second speed higher than the first speed (e.g., at a second frame rate higher than the first frame rate), and transmit an encoded image signal to the application processor 1200. At this time, the second speed may be at most 30 times the first speed.

The application processor 1200 may store the received image signal, i.e., the encoded image signal, in the internal memory 1230 therein or the external memory 1400 outside the application processor 1200. Thereafter, the application processor 1200 may readout the encoded image signal from the internal memory 1230 or the external memory 1400, decode the encoded image signal, and display image data generated based on a decoded image signal. For example, a corresponding one of the sub image processors 1212a, 1212b, or 1212c of the image processing unit 1210 may perform the decoding and may also perform image processing on the decoded image signal.

In the second operation mode, the camera modules 1100a, 1100b, and 1100c may generate an image signal at a third speed lower than the first speed (e.g., at a third frame rate lower than the first frame rate) and transmit the image signal to the application processor 1200. The image signal provided to the application processor 1200 may not have been encoded. The application processor 1200 may perform image processing on the image signal or store the image signal in the internal memory 1230 or the external memory 1400.

The PMIC 1300 may provide power, e.g., a power supply voltage, to each of the camera modules 1100a, 1100b, and 1100c. For example, under control by the application processor 1200, the PMIC 1300 may provide first power to the camera module 1100a through a power signal line PSLa, second power to the camera module 1100b through a power signal line PSLb, and third power to the camera module 1100c through a power signal line PSLc.

The PMIC 1300 may generate power corresponding to each of the camera modules 1100a, 1100b, and 1100c and adjust the level of the power, in response to a power control signal PCON from the application processor 1200. The power control signal PCON may include a power adjustment signal for each operation mode of the camera modules 1100a, 1100b, and 1100c. For example, the operation mode may include a low-power mode. At this time, the power control signal PCON may include information about a camera module to operate in the low-power mode and a power level to be set. The same or different levels of power may be respectively provided to the camera modules 1100a, 1100b, and 1100c. The level of power may be dynamically changed.

As described herein, any devices, systems, modules, portions, units, controllers, circuits, and/or portions thereof according to any of the example embodiments, and/or any portions thereof (including, without limitation, the image sensor 100, the pixel array 110, the row driver 120, the readout circuit 130, the ADC circuit 131, the data bus 132, the ramp signal generator 140, the timing controller 150, the signal processor 190, the electronic device 1000, the plurality of camera modules 1100a, 1100b, and 1100c, the prism 1105, the optical path folding element OPFE 1110, the actuator 1130, the image sensing device 1140, the image sensor 1142, the control logic 1144, the memory 1146, the storage 1150, the application processor 1200, the image processing unit 1210, the plurality of sub image processors 1212a, 1212b, and 1212c, the image generator 1214, the camera module controller 1216, the memory controller 1220, the internal memory 1230, the PMIC 1300, the external memory 1400, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

While the inventive concepts have been particularly shown and described with reference to some example embodiments thereof, it will be understood that various changes in form and details may be made therein without departing from the spirit and scope of the following claims.

What is claimed is:

1. A pixel including a first photodiode and a second photodiode, the second photodiode having a different light-receiving area from that of the first photodiode, the pixel comprising:
a semiconductor substrate;
a first pixel region in the semiconductor substrate and having the first photodiode therein;
a second pixel region in the semiconductor substrate and having the second photodiode therein; and
a pixel isolation film at a surface where the first pixel region and the second pixel region are in contact with each other,
wherein an area of the first pixel region is larger than an area of the second pixel region, and
wherein the pixel isolation film includes a first pixel isolation film and a second pixel isolation film, the second pixel isolation film separated from the first pixel isolation film.

2. The pixel of claim 1, further comprising:
a first transfer transistor configured to transfer charges accumulated in the first photodiode; and
a second transfer transistor configured to transfer charges accumulated in the second photodiode,
wherein a gate electrode of the second transfer transistor is in an active portion, and
wherein the active portion extends between the first pixel region and the second pixel region.

3. The pixel of claim 2, wherein
the active portion is between the first pixel isolation film and the second pixel isolation film.

4. The pixel of claim 2, further comprising:
a first floating diffusion region configured to cumulatively store charges generated by the first photodiode; and
a third floating diffusion region configured to cumulatively store charges generated by the second photodiode,
wherein the third floating diffusion region is in the active portion.

5. An image sensor including a pixel including a plurality of photodiodes having different light-receiving areas, the image sensor comprising:
a semiconductor substrate of a first conductivity type, the semiconductor substrate including a first pixel region and a second pixel region;
a first photodiode of a second conductivity type, the first photodiode in the first pixel region;
a second photodiode of the second conductivity type, the second photodiode in the second pixel region, the second photodiode having a different light-receiving area than a light-receiving area of the first photodiode;
a first floating diffusion region, the first floating diffusion region configured to accumulate charges of the first photodiode; and
a third floating diffusion region, the third floating diffusion region configured to accumulate charges of the second photodiode,
wherein the first floating diffusion region is in the first pixel region, and
wherein the third floating diffusion region extends between the first pixel region and the second pixel region.

6. The image sensor of claim 5, wherein
an impurity doping concentration in the first floating diffusion region is greater than an impurity doping concentration in the third floating diffusion region.

7. The image sensor of claim 5, further comprising:
a first well impurity region of the first conductivity type, the first well impurity region in the first pixel region.

8. The image sensor of claim 5, further comprising:
a second well impurity region of the first conductivity type, the second well impurity region in the second pixel region.

9. The image sensor of claim 5, further comprising:
a pixel isolation film at a surface where the first pixel region and the second pixel region are in contact with each other,
wherein the pixel isolation film includes a first pixel isolation film and a second pixel isolation film separated from the first pixel isolation film.

10. An image sensor, comprising:
a plurality of pixels in a semiconductor substrate, wherein each pixel of the plurality of pixels includes
a first photodiode,
a second photodiode adjacent to the first photodiode, the second photodiode having a smaller light-receiving area than a light-receiving area of the first photodiode,
a first transfer transistor having an end connected to the first photodiode and an opposite end connected to a first floating diffusion node,
a first conversion gain transistor having an end connected to the first floating diffusion node and an opposite end connected to a second floating diffusion node,
a second transfer transistor having an end connected to the second photodiode and an opposite end connected to a third floating diffusion node,
a second conversion gain transistor having an end connected to the third floating diffusion node and an opposite end connected to a fourth floating diffusion node,
a first switching transistor having an end connected to the second floating diffusion node and an opposite end connected to the third floating diffusion node, and
a capacitor having an end connected to the fourth floating diffusion node and an opposite end connected to a pixel voltage source,
wherein the first photodiode, the first transfer transistor, the first conversion gain transistor, the second conversion gain transistor, and the first switching transistor are in a first pixel region of the semiconductor substrate,
wherein the second photodiode and the second transfer transistor are in a second pixel region of the semiconductor substrate,
wherein the second transfer transistor, the first switching transistor, and the second conversion gain transistor share a region corresponding to the third floating diffusion node, and
wherein the region corresponding to the third floating diffusion node extends between the first pixel region and the second pixel region of the semiconductor substrate.

11. The image sensor of claim 10, wherein the semiconductor substrate includes
a pixel isolation film at a surface where the first pixel region and the second pixel region are in contact with each other, and
the pixel isolation film includes a first pixel isolation film and a second pixel isolation film, the second pixel isolation film separated from the first pixel isolation film.

12. The image sensor of claim 11, wherein
the region corresponding to the third floating diffusion node is between the first pixel isolation film and the second pixel isolation film.

13. The image sensor of claim 11, wherein each pixel of the plurality of pixels further includes a first overflow gate transistor connected to the first photodiode.

14. The image sensor of claim 11, wherein each pixel of the plurality of pixels further includes a second overflow gate transistor connected to the second photodiode.

15. The image sensor of claim 11, wherein
an impurity doping concentration in a region corresponding to the first floating diffusion node is greater than an impurity doping concentration in the region corresponding to the third floating diffusion node.

16. The image sensor of claim 11, wherein
an impurity doping concentration in a region corresponding to the second floating diffusion node is greater than an impurity doping concentration in the region corresponding to the third floating diffusion node.

17. The image sensor of claim 11, wherein
each pixel of the plurality of pixels further includes a first well impurity region in the first pixel region, the first well impurity region being of a same first conductivity type as the semiconductor substrate.

18. The image sensor of claim 11, wherein
each pixel of the plurality of pixels further includes a second well impurity region in the second pixel region, the second well impurity region being of a same first conductivity type as the semiconductor substrate.

19. The image sensor of claim 11, wherein
each pixel of the plurality of pixels further includes a contact connected to the fourth floating diffusion node.

20. The image sensor of claim 11, wherein each pixel of the plurality of pixels further includes a ground in the first pixel region.
